(19) United States
(12) Patent Application Publication
(10) Pub. No.: US 2007/0262051 A1
(43) Pub. Date: Nov. 15, 2007

(54) METHOD OF PLASMA ETCHING WITH PATTERN MASK

(75) Inventors: Wen-Kun Yang, Hsin-Chu City (TW); Jui-Hsien Chang, Jhudong Township (TW); Wen-Bin Sun, Taipei (TW)

Correspondence Address: KUSNER & JAFFE;HIGHLAND PLACE SUITE 310, 6151 WILSON MILLS ROAD, HIGHLAND HEIGHTS, OH, 44143, US

(73) Assignee: Advanced Chip Engineering Technology Inc.

(21) Appl. No.: 11/382,958

(22) Filed: May 12, 2006

(51) Int. Cl. C03C 25/68; C23F 1/00; H01L 21/306

(52) U.S. Cl. 216/67; 216/58; 216/79; 156/345.3; 156/345.33

(57) ABSTRACT

The present invention provides a method of plasma etching with pattern mask. There are two different devices in the two section of a wafer, comprising silicon and Gallium Arsenide (GaAs). The Silicon section is for general semiconductor. And the GaAs section is for RF device. The material of pad in the silicon is usually metal, and metal oxide is usually formed on the pads. The metal oxide is unwanted for further process; therefore it should be removed by plasma etching process. A film is attached to the surface of the substrate exposing the area need for etching. Then a mask is attached and aligned onto the film therefore exposing the area need for etching. Then plasma dry etching is applied on the substrate for removing the metal oxide.

### FIELD OF THE INVENTION

This invention relates to an etching method for package assembly, and particularly, to a method of plasma etching with a pattern mask.

### BACKGROUND OF THE INVENTION

### Description of the Prior Art

In the process and manufacture of semiconductor, it is necessary to etch the thin films previously deposited and/or the substrate itself. In general, there are two classes of etching processes, that is: wet etching and dry etching. Wet etching is to dissolve the material when immersed in a chemical solution, while dry is to sputter or dissolve etching the material using reactive ions or plasma. A disadvantage of wet etching is the undercutting caused by the isotropy of etch. The purpose of dry etching is to create an anisotropic etch—meaning that the etching is uni-directional. An anisotropic etch is critical for high-fidelity pattern transfer.

The fluorine ions are accelerated in the electric field causing them to collide into the surface of the sample or the etching region, where they combine with silicon dioxide and then are dispersed. Because the electric field accelerated ions toward the surface, the etching caused by these ions is much more dominant than the etching of radicals—ions traveling in varied directions, so the etching are anisotropic. In dry etching process, a hard mask is used to protect certain areas from etching, exposing only the areas desired to be etched. Conventionally, RIE or plasma etching employs photoresist as an etching pattern.

The etching for packaging assembly is quite different from the etching to the chips formation. A certain process maybe introduced to remove the native oxide formed on the metal pad. Typically, it is likely to remove the undesired material by wet etching when the wafer includes general silicon based device formed thereon. However, if a wafer or substrate to be packaged includes different species of devices, for example, one includes aluminum pad and other includes gold pad. As known, oxide is likely to be formed on the aluminum pad. Thus, an etching is necessary to remove the oxide formed thereon. However, a blanket etching or wet etching will damage the part of wafer without the oxide formation, for instance, the gold pad. The conventional method will cause the gold pad to be damage when the blank etching is performed for package assembly. Besides, it is hard to increase the quantity of output effectively. What is desired is a new method for package assembly in order to overcome these problems.

### SUMMARY OF THE INVENTION

The main purpose of the present invention is to provide a method of plasma etching with pattern mask for packaging a wafer instead of an individual chip. The pattern mask is attached on a film formed on a wafer having first device and a second device, for exposing only the areas desired to be etched. There are no exposure or development steps needed for pattern mask. Therefore, the advantage of the present invention is to provide a simplify process method for plasma or RIE etching which improves the quantity of output effectively.

Besides, another advantage of the present invention is that the present invention provides a dry etching system with a mask attaching module which is inexpensive than PR coating module. Besides, the PR coating process, including hard bake for drying the water, therefore it takes more time for conventional PR process.

The present invention may be applied to the removal of layer, material formed on an area of signal die. Furthermore, the material under removing is not limited to oxide, any undesired material could be removed by the present invention. For example, the present invention can be applied to remove unwanted coating on a CMOS sensor.

The main purpose of the present invention is to provide a method of etching, comprises: providing a mask having a buffer film formed thereon, wherein the mask has at least one air opening formed through the mask to the buffer later; attaching the mask on a wafer through the buffer film to cover a portion of the wafer to allow the at least one air opening expose an area to be etched, wherein the wafer including a silicon based area and a GaAs based area, and the wafer includes a die having at least one area under etching; the material of the buffer film includes elastic material, for instance, silicone resin, elastic PU, porous PU, acrylic rubber, blue tape, UV tape, polyimide (PI), polyester (PET), or polypropylene (BOPP); the material of the mask could be nonconductive material; and performing a dry etching through the at least one air opening, and the dry etching includes plasma etching.

Another purpose of the present invention is to provide a dry etching system, wherein the dry etching system comprises plasma etching system or reactive ion etching (RIE) system, the dry etching system comprises: a control unit for controlling the dry etching system; a power source coupled to the control unit to provide bias for generating plasma; an inputting and setting section coupled to the control unit for inputting and setting process condition; a vacuum unit coupled to the control unit to vacuum a chamber of a processed wafer; and a mask attaching module coupled to the control unit to attach and align a mask on the processed wafer, and the mask includes nonconductive material, and the mask includes air openings and a buffer layer formed thereon.

Besides, the present invention also provides a dry etching system, comprises: a plasma etching system, the plasma etching system comprises reactive ion etching (RIE) system; and a mask attaching module coupled to the plasma etching system to attach and align a mask on a processed wafer in a chamber, the material of said mask includes nonconductive material. Besides, the mask includes air openings and a buffer layer formed thereon.

### BRIEF DESCRIPTION OF THE DRAWINGS

The above objects, and other features and advantages of the present invention will become more apparent after reading the following detailed description when taken in conjunction with the drawings, in which:

FIG. 1A˜1D is a diagram of a dry etching process of the present invention.

FIG. 1E is a diagram of a dry etching process of another embodiment of the present invention.

FIG. 2 is a block diagram of a RIE etcher controlling system of the present invention.

### DESCRIPTION OF THE PREFERRED EMBODIMENT

Some sample embodiments of the invention will now be described in greater detail. Nevertheless, it should be recognized that the present invention can be practiced in a wide range of other embodiments besides those explicitly described, and the scope of the present invention is expressly not limited expect as specified in the accompanying claims. Then, the components of the different elements are not shown to scale. Some dimensions of the related components are exaggerated and meaningless portions are not drawn to provide clearer description and comprehension of the present invention.

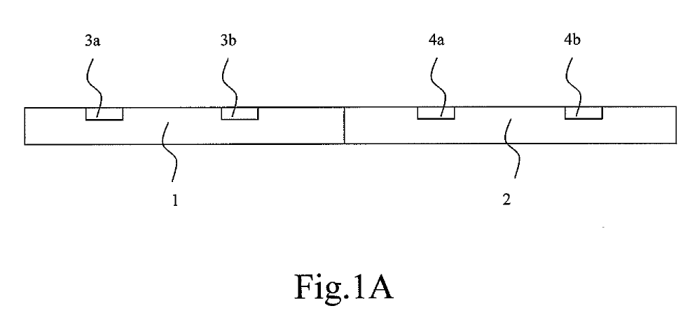

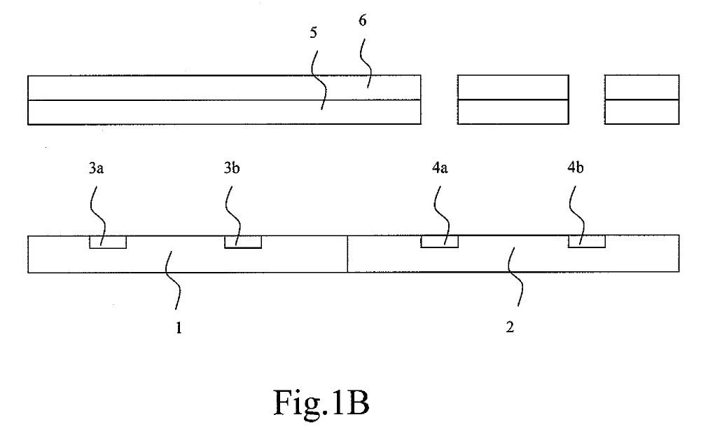

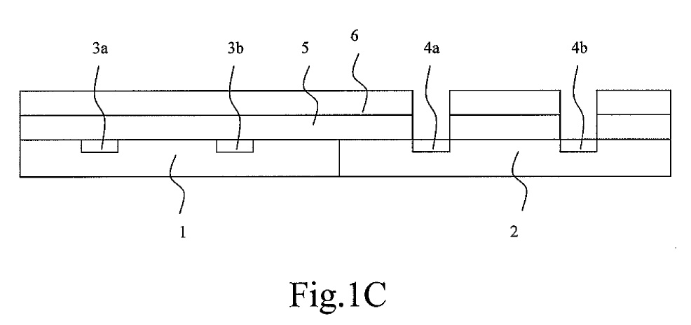

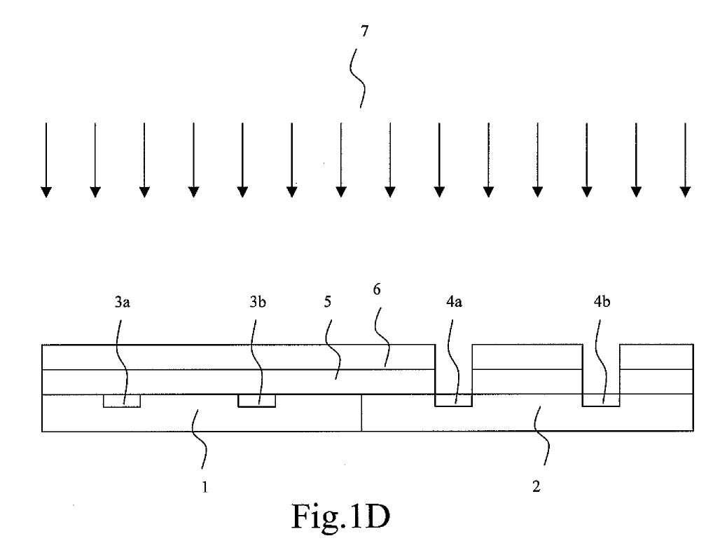

The present invention discloses a method for plasma etching. Serial steps of the method are shown in FIG. 1A to FIG. 1D separately. First, a wafer including at least two different areas 1 and 2 on the wafer is provided as shown in FIG. 1A, the materials of the areas 1 and 2 maybe silicon and Gallium Arsenide (GaAs), respectively. The areas 1 and 2 are used for forming two different species of devices. For example, the silicon area 2 maybe a conventional semiconductor substrate, while the GaAs substrate 1 is usually for manufacturing RF device.

The bonding pad material is selected according the type of device. For instance, the silicon based device has the aluminum pad and the material for the RF device is gold. In the illustration, the bonding pads 3a, 3b and pads 4a, 4b are formed on the top surface of GaAs area 1 and silicon area 2 separately for wire bonding. Typically, the material of pads 4a and 4b is metal such as Aluminum, while the material of pads 3a and 3b is gold. Metal oxide is likely to be formed on the surface of Aluminum pads 4a, and 4b. The native oxide must be removed by etching during the packaging assembly. As aforementioned, the blank etching and wet etching by conventional method will induce side effect.

A buffer film 5 with pattern is subsequently attached to the bottom of the mask 6 as shown in FIG. 1B. The pattern of the buffer film 5 is aligned with the pattern of the mask 6. The buffer film 5 is preferably made of insulating material includes: silicone resin, elastic PU, porous PU, acrylic rubber, blue tape or UV tape, polyimide (PI), polyester (PET), and polypropylene (BOPP). The buffer film 5 has the characteristic of viscosity or adhesive for attaching the mask 6 to the wafer, and the buffer film 5 is formed by a printing, coating, tapping or molding method.

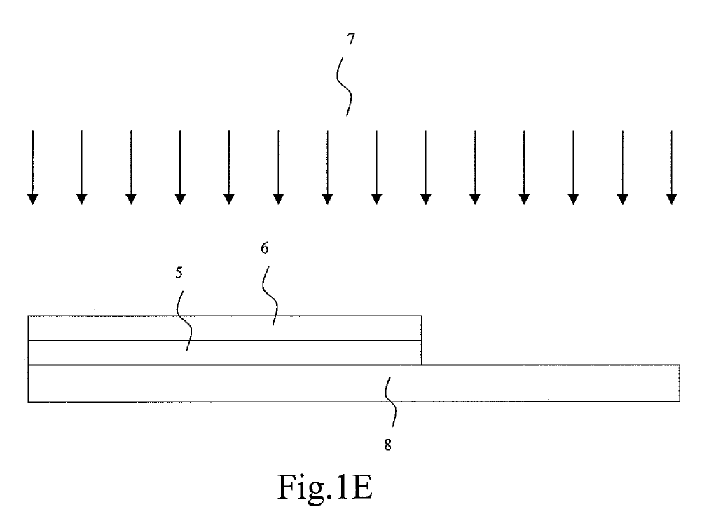

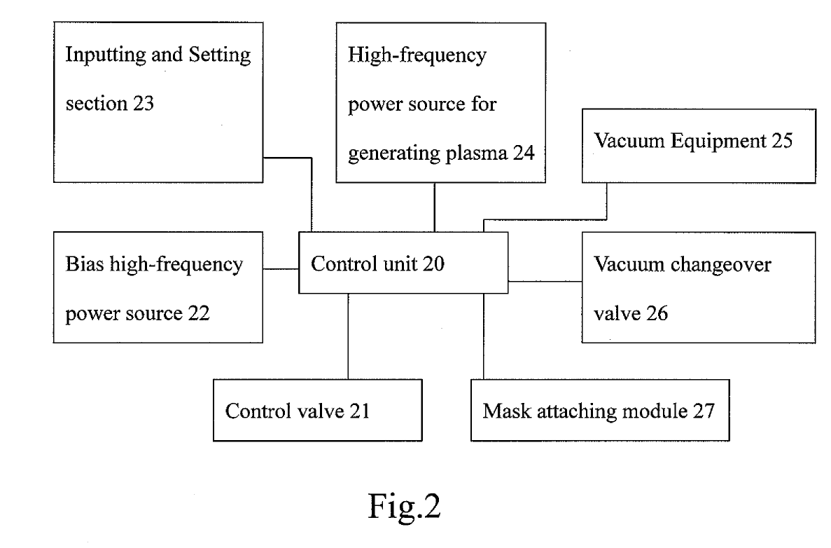

The mask 6 is attached on the surface of the wafer through the buffer film 5 as shown in FIG. 1C, wherein the mask 6 and the buffer film 5 have air openings to expose the silicon based area and cover the GaAs based area, respectively. In the embodiment of the present invention, the mask 6 exposes the aluminum pads 4a and 4b. The buffer film 5 is formed between the mask 6 and the wafer, therefore the mask 6 is not attached to the wafer directly for protecting the surface of the wafer. The buffer film 5 can be used for protecting the surface of the GaAs based area where is not desired to be etched. It should be noted that the mask 6 is different from the photomask for lithography. The ions may pass though the mask 6 via the air opening, not like the convention photomask, it includes transparent material aligned to the opening to allow the illumination to pass through. The air openings of the pattern mask 6 are aligned to and expose the aluminum pads 4a, and 4b in the embodiment of the present invention. A mask attaching module 27 (please refers to FIG. 2) is used for attaching the mask 6 on the wafer.

Dry etching is performed, for example, applying plasma 7 on the areas 1 and 2 as shown in FIG. 1D for removing metal oxide on aluminum pads 4a and 4b. Preferably, the dry etching is provided by RIE etcher, electron cyclotron resonance plasma, inductively coupled plasma etcher, helicon wave plasma etcher, or cluster plasma process. The aforesaid etching apparatus includes mask attaching module 27.

The mask 6 and the buffer film 5 can also be formed on the surface of single die 8 in one embodiment of the present invention as shown in FIG. 1E. Therefore, the mask 6 exposes the portion of the die 8 to be etched by plasma 7, and covers the portion of the die 8 for protection.

Therefore, the present invention provides undesired material removal method for package. The mask 6 with air opening is attached on the substrate to expose the part of the substrate to be etched by plasma, and to protect the part of the substrate covered be the mask 6. Alternatively, the material under removing is not limited to oxide, any undesired material could be removed by the present invention. For example, in the application for CMOS sensor, the present invention can be applied to remove unwanted layer such as coating on the area except for the lens area.

FIG. 2 shows a block diagram of a plasma dry etcher system according to another embodiment of the present invention. The dry etching system comprises a control unit 20, a control valve 21, a bias high-frequency power source 22, n inputting and setting section, a high-frequency power source for generating plasma 24, a vacuum equipment 25, a vacuum changeover valve 26 and mask attaching module 2. The control unit 20 usually comprises a computer system. The control valve 21 is controller by the control unit 20 so as to alternately switch the control gases in the atmosphere of the vacuum plasma chamber between an etching gas and a deposition gas, thereby alternately conducting the etching of the silicon substrate. And when switching the process gases, the control unit 20 controls the vacuum changeover valve 26 and the control valves 21 and so as to vacuum out the vacuum plasma chamber by the vacuum equipment 25 thereby causing inner pressure to become equal to or below 10⁻² Pa. Generally, the vacuum equipment 25 includes dry and turbo pump. Thus, the process gas (etching gas) that has just finished being used is sufficiently vacuumed away.

Furthermore, the control unit 20 sets the high-frequency power 24 (voltage) and the bias power (voltage) 22 for generating plasma based on the preset conditions that have been inputted from the inputting and setting section 23, thereby controlling the time for the etching process, deposition process, and vacuuming process as well as controlling the flow rate of the etching gas and deposition gas. The dry etching system according to the present invention further comprises a mask attaching module 27 coupled to the control unit 20 for attaching and aligning mask on the surface of the buffer film 5 before etching.

According to the above description, the present invention provides a dry etching system, comprising a mask attaching module coupled to the control unit 20 for attaching and aligning mask on the surface film to expose area for etching. The process of the pattern mask is more simple and easier than conventional method. The quantity of the production can be improved effectively.

Although specific embodiments have been illustrated and described, it will be obvious to those skilled in the art that various modifications may be made without departing from what is intended to be limited solely by the appended claims.

Having described the invention, the following is claimed:

1. A method of etching, comprises:
providing a mask having a buffer film formed thereon, wherein said mask has at least one air opening formed through said mask to said buffer later;
attaching said mask on a wafer through said buffer film to cover a portion of said wafer to allow said at least one air opening expose an area to be etched; and
performing a dry etching through said at least one air opening.

2. The method of etching in claim 1, wherein said wafer including a silicon based area and a GaAs based area.

3. The method of etching in claim 1, wherein said wafer includes a die having at least one area under etching.

4. The method of etching in claim 1, wherein said dry etching includes plasma etching.

5. The method of etching in claim 1, wherein the material of said buffer film includes elastic material.

6. The method of etching in claim 1, wherein said buffer film includes silicone resin.

7. The method of etching in claim 1, wherein said buffer film includes elastic PU.

8. The method of etching in claim 1, wherein said buffer film includes porous PU.

9. The method of etching in claim 1, wherein said buffer film includes acrylic rubber.

10. The method of etching in claim 1, wherein said buffer film includes blue tape.

11. The method of etching in claim 1, wherein said buffer film includes UV tape.

12. The method of etching in claim 1, wherein said buffer film includes polyimide (PI).

13. The method of etching in claim 1, wherein the said buffer film includes polyester (PET).

14. The method of etching in claim 5, wherein the elastic material includes polypropylene (BOPP).

15. The method of etching in claim 1, wherein the material of said mask includes nonconductive material.

16. A dry etching system, comprises:
a control unit for controlling said dry etching system;
a power source coupled to said control unit to provide bias for generating plasma;
an inputting and setting section coupled to said control unit for inputting and setting process condition;
a vacuum unit coupled to said control unit to vacuum a chamber of a processed wafer; and
a mask attaching module coupled to said control unit to attach and align a mask on said processed wafer.

17. The dry etching system in claim 16, wherein said dry etching system comprises plasma etching system.

18. The dry etching system in claim 16, wherein said dry etching system comprises reactive ion etching (RIE) system.

19. The dry etching system in claim 16, wherein said material of said mask includes nonconductive material.

20. The dry etching system in claim 16, wherein said mask includes air openings formed thereon.

21. The dry etching system in claim 16, wherein said mask includes a buffer layer formed thereon.

22. A dry etching system, comprises:
a plasma etching system; and
a mask attaching module coupled to said plasma etching system to attach and align a mask on a processed wafer in a chamber.

23. The dry etching system in claim 22, wherein said plasma etching system comprises reactive ion etching (RIE) system.

24. The dry etching system in claim 22, wherein the material of said mask includes nonconductive material.

25. The dry etching system in claim 22, wherein the mask includes air openings formed thereon.

26. The dry etching system in claim 22, wherein said mask includes a buffer layer formed thereon.
